(19) United States
(12) Patent Application Publication
(10) Pub. No.: US 2009/0178701 A1
(43) Pub. Date: Jul. 16, 2009

(54) Apparatus and methods for sealing an electrical connection to at least one elongated photovoltaic module

(75) Inventors: Andrew Nagengast, Fremont, CA (US); Thomas Brezoczky, Fremont, CA (US)

Correspondence Address: Jones & Smith, LLP;Attn: Randy Smith, 2777 Allen Parkway, Suite 800, Houston, TX, 77019, US

(73) Assignee: Solyndra, Inc., Fremont, CA (US)

(21) Appl. No.: 12/011,533

(22) Filed: Jan. 28, 2008

Related U.S. Application Data
(60) Provisional application No. 61/001,605, filed on Nov. 2, 2007.
(60) Provisional application No. 60/994,696, filed on Sep. 21, 2007.

(51) Int. Cl. H01L 31/042; B23P 19/00

(52) U.S. Cl. 136/244; 29/729

(57) ABSTRACT

In some embodiments, an apparatus for producing electric energy from light energy includes an elongated photovoltaic module (EPM) and a cover engageable therewith. The EPM includes at least one electrical output contact and the cover includes at least one electrical connector operable to electrically engage at least one electrical output contact(s). The cover sealingly engages the EPM around at least one of its electrical output contact(s).

This application claims priority to U.S. provisional application Ser. Nos. 61/001,605 filed on Nov. 2, 2007 and entitled “Apparatus and Methods for Sealing an Electrical Connection to at Least one Elongated Photovoltaic Module” and 60/994,696 filed on Sep. 21, 2007 and entitled “Apparatus and Methods for Retaining a Plurality of Elongated Photovoltaic Modules”, both of which are hereby incorporated by reference herein in their entireties.

### BACKGROUND

This patent relates to photovoltaic energy absorption/collection technology, and, in particular, apparatus and methods for sealing electrical connections to elongated photovoltaic modules.

FIG. 1 is a schematic diagram of a typical active photovoltaic (PV) device, or solar cell, 2. The active PV device 2 includes a back electrode layer 4, a PV material 5 and a front electrode 6. Light energy is transmitted to the PV layer 5, where it is absorbed and transformed into electric energy. The electricity generated within the PV device 2 migrates to either the front electrode 6 or the back electrode 4, from where it is directed out of the cell through an electrical contact 7 or 8.

The front electrode 6 may, for example, include a transparent layer, such as transparent conductive material, that allows the light to pass through it. For another example, the front electrode 6 may be constructed of one or more opaque materials spread lattice-like placed atop the PV layer 5. The PV layer 5 may be constructed of any among many different types of materials, including, but not limited to, semiconductor junctions, organic-dye based materials, photoelectrochemical cells, polymer solar cells, nanocrystal solar cells or dye sensitized solar cells, as well as other PV cell technologies

For the purpose of this disclosure, a photovoltaic module includes one or more active PV devices disposed upon a common substrate or different substrates. When more than one PV device is included, the PV devices can be coupled together electrically, either in parallel or in series.

Photovoltaic (PV) energy absorption/collection devices, such as solar panels, typically include one or more photovoltaic modules held in a carrier structure or framework. The structure or framework provides for an electrical connection to the photovoltaic module(s) in order to receive and use the electric energy formed by the module(s).

### BRIEF DESCRIPTION OF THE DRAWINGS

The following figures are part of the present specification, included for background purposes or to demonstrate certain aspects of embodiments of the present disclosure and referenced in the detailed description herein:

FIG. 1 is a schematic diagram of an exemplary Prior Art active photovoltaic (PV) device, or solar cell.

FIG. 2 is a partial cross-sectional view of an elongated photovoltaic module with an end cover in accordance with an embodiment of the present disclosure.

FIG. 3 is a cross-sectional view of the exemplary elongated photovoltaic module of FIG. 2 taken along lines 3-3.

FIG. 4 is a perspective view of an embodiment of a carrier assembly made in accordance with the present disclosure and shown holding a plurality of elongated photovoltaic modules;

FIG. 5 is a cross-sectional view of an example elongated photovoltaic module show in FIG. 4 taken along lines 5-5;

FIG. 6 is a cross-sectional view of an exemplary receptacle of one of the carriers of the carrier assembly shown in FIG. 4 taken along lines 6-6;

FIG. 7 is a side view of an embodiment of a carrier in accordance with the present disclosure shown in a partially folded state;

FIG. 8 is an exploded view of a portion of the exemplary carrier shown in FIG. 7;

FIG. 9 is a perspective view of another embodiment of a carrier assembly made in accordance with the present disclosure and shown holding a plurality of photovoltaic modules;

FIG. 10 is a top view of yet another embodiment of a carrier assembly made in accordance with the present disclosure and shown holding a plurality of photovoltaic modules;

FIG. 11 is a front view of the carrier assembly shown in FIG. 10;

FIG. 12 is an isolated view of an embodiment of a connector made in accordance with the present disclosure;

FIG. 13 is an isolated view of another embodiment of a connector made in accordance with the present disclosure;

FIG. 14 is an isolated view of yet another embodiment of a connector made in accordance with the present disclosure;

FIG. 15 is a partial perspective view of an example photovoltaic module being sealingly engaged with an exemplary receptacle of one of the carriers of the carrier assembly shown in FIG. 4 in accordance with an embodiment of the present disclosure;

FIG. 16 is a partial cut-away view of the embodiment of FIG. 15 showing the example photovoltaic module engaged with the exemplary receptacle; and

FIG. 17 is an exploded view of the embodiment of FIG. 16 showing the sealing engagement of the example photovoltaic module and the exemplary receptacle.

### DETAILED DESCRIPTION

Characteristics and advantages of the present disclosure and additional features and benefits will be readily apparent to those skilled in the art upon consideration of the following detailed description and referring to the accompanying figures. It should be understood that the description herein and appended drawings are of various exemplary embodiments and are not intended to limit the appended claims or the claims of any patent or patent application claiming priority hereto. On the contrary, the intention is to cover all modifications, equivalents and alternatives falling within the spirit and scope of the claims. Many changes may be made to the particular embodiments and details disclosed herein without departing from such spirit and scope.

In the description below and appended figures, like or identical reference numerals are used to identify common or similar elements. The figures are not necessarily to scale and certain features and certain views of the figures may be shown exaggerated in scale or in schematic in the interest of clarity and conciseness. It should also be noted that reference herein and in the appended claims to components and aspects in a singular tense does not necessarily limit the present disclosure or claims to only one such component or aspect, but should be interpreted generally to mean one or more, as may be suitable and desirable in each particular instance.

Referring initially to FIG. 2, an elongated photovoltaic (PV) module 16 in accordance with an embodiment of the present disclosure is shown. The illustrated elongated PV module 16 (or simply the “module 16”) allows electricity generated within it to be output through one or more electrical output contacts 19 disposed at one or more ends 18 of the module 16. An end cover 23 is shown engaged with the exemplary module 16 around the electrical output contact 19 to isolate the contact 19 from the external environment.

The end cover 23 may have any suitable form and may be engageable with the module 16 in any suitable manner. For example, the end cover 23 may grip or mate with the module 16 around the perimeter (FIG. 3) of a non-electrically conducting part or surface of the module 16. If desired, the end cover 23 may sealingly engage the module 16 to seal off or electrically isolate the output contact 19, such as from moisture from the external environment. For example, a sealant (not shown) may be applied or placed between the end cover 23 and module 16 around the module 16 to seal off any spaces between the cover 23 and the module 16.

The end cover 23 of this embodiment may also have an additional member or members (not shown) associated with it that electrically engage the electrical output contact 19 of the module 23 and can be used to communicate electric energy from the module 16 therethrough to a desired destination. For example, an electrical connector (not shown), such as a wire, socket or leaf member, may be disposed within the end cover 23 and engageable with the electrical output contact 19 to communicate the electric energy from the contact 19 to a desired destination outside the end cover 23.

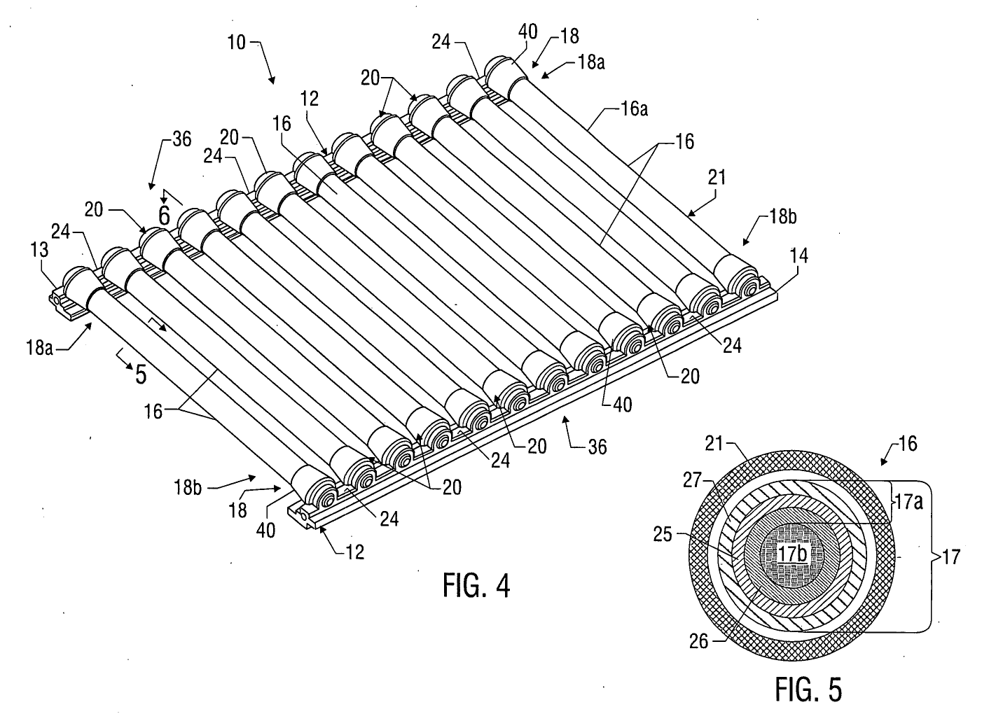

If desired, one or more modules 16 with isolated or sealed electrical output ends 18 or contacts 19 may be included in a device or system that couples several elongated PV modules 16 together. Referring to FIG. 4, for example, a carrier assembly 10 made in accordance with an embodiment of the present disclosure includes at least one carrier 12 shown holding at least two elongated PV modules 16. Each carrier 12 includes at least two adjacent receptacles 20. The carrier may, if desired, be moveable between the receptacles. As used herein, the term “movable” and variations thereof means flexible, bendable, foldable, hinged, or the like, sufficient to enable the position or relationship of adjacent receptacles to be changed relative to one another.

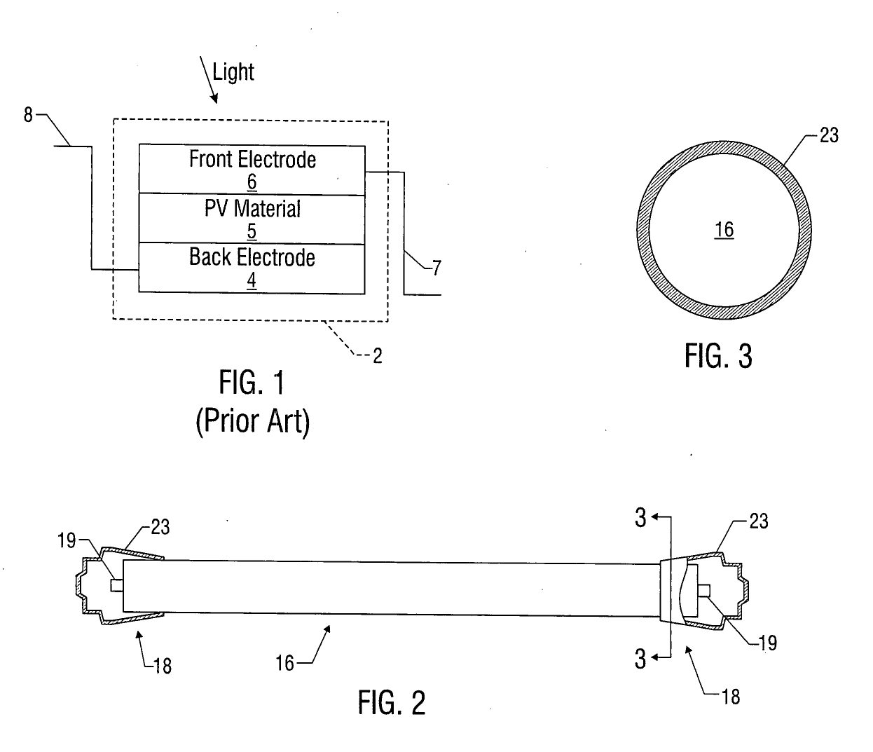

Each illustrated receptacle 20 is capable of firmly engaging an end 18 of at least one elongated photovoltaic module 16. When the exemplary carrier assembly 10 includes carriers 12 engaged with opposite ends 18 of at least two elongated photovoltaic modules 16, such as the embodiment of FIG. 1, the carriers 12 form a framework for holding the elongated photovoltaic modules 16. If the carriers 12 are movable between receptacles 20, they may be concurrently movable between respective adjacent engaged elongated photovoltaic modules 16.

The present disclosure may utilize any suitable elongated PV modules 16. Thus, the present disclosure and appended claims are not limited by the elongated photovoltaic modules 16 (except as may be expressly recited in any particular claims and only with respect thereto). Further, different types and configurations of elongated PV modules 16 may be used in the same carrier assembly 10.

For purposes of this discussion, an elongated photovoltaic module 16 is characterized by having a longitudinal dimension and a width dimension. In some embodiments, for example, the longitudinal dimension of the elongated PV module 16 exceeds the width dimension by at least a factor of 4, at least a factor of 5, or at least a factor of 6. In some embodiments, the longitudinal dimension of the module 16 is 10 centimeters (cm) or greater, 20 cm or greater, or 100 cm or greater. In some embodiments, the width dimension of the module 16 is a diameter of 500 mm or more, 1 cm or more, 2 cm or more, 5 cm or more, or 10 cm or more. However, the present disclosure and appended claims are not limited to any such examples (except as may be expressly recited in any particular claims and only with respect thereto).

The modules 16 may likewise have any suitable construction and configuration. In the example of FIG. 5, the module 16 has a generally cylindrical overall shape and a generally circular cross-sectional shape to capture light from any direction. However, as mentioned infra, the elongated module 16 may take many shapes.

Still referring to FIG. 5, each illustrated module 16 includes an active photovoltaic structure 17 and an outer protective structure 21 at least partially surrounding the photovoltaic structure 17. The outer protective structure 21 may, for example, be a shell that defines an inner volume within which the photovoltaic structure 17 is contained, such as to protect the photovoltaic structure 17. The outer protective structure would allow light energy to pass from outside the module 16 to the photovoltaic structure 17, or perform any other suitable purpose or a combination thereof. In many embodiments, the outer protective structure 21 may be constructed of material that allows substantial light energy to pass through it, such as, but not limited to, plastics, glasses and transparent ceramics. An example outer protective structure 21 is a tubular glass casing.

Referring still to the example of FIG. 5, the active photovoltaic structure 17 of the illustrated module 16 includes at least one photovoltaic cell 17a, operable to convert light energy to electric energy, disposed upon at least one substrate 17b. The substrate 17b may have any suitable form. For example, the substrate may be elongated or non-elongated; rigid, partially rigid or non-rigid; solid, hollow, or a combination thereof; closed at either or both ends, or open at both ends. An example substrate 17b is a solid and rigid elongated glass rod.

Rigidity of a material can be measured using several different metrics including, but not limited to, Young's modulus. In solid mechanics, Young's Modulus (E) (also known as the Young Modulus, modulus of elasticity, elastic modulus or tensile modulus) is a measure of the stiffness of a given material. It is defined as the ratio, for small strains, of the rate of change of stress with strain, which can be experimentally determined from the slope of a stress-strain curve created during tensile tests conducted on a sample of the material. Young's modulus for various materials is given in the following table.

| | Young's modulus (E) | Young's modulus (E) in |
|---|---|---|
| Material | in GPa | lbf/in² (psi) |
| Rubber (small strain) | 0.01-0.1 | 1,500-15,000 |
| Low density polyethylene | 0.2 | 30,000 |
| Polypropylene | 1.5-2 | 217,000-290,000 |
| Polyethylene terephthalate | 2-2.5 | 290,000-360,000 |
| Polystyrene | 3-3.5 | 435,000-505,000 |
| Nylon | 3-7 | 290,000-580,000 |
| Aluminum alloy | 69 | 10,000,000 |
| Glass (all types) | 72 | 10,400,000 |
| Brass and bronze | 103-124 | 17,000,000 |
| Titanium (Ti) | 105-120 | 15,000,000-17,500,000 |
| Carbon fiber reinforced plastic | 150 | 21,800,000 |
| (unidirectional, along grain) | | |
| Wrought iron and steel | 190-210 | 30,000,000 |
| Tungsten (W) | 400-410 | 58,000,000-59,500,000 |
| Silicon carbide (SiC) | 450 | 65,000,000 |
| Tungsten carbide (WC) | 450-650 | 65,000,000-94,000,000 |
| Single Carbon nanotube | 1,000+ | 145,000,000 |
| Diamond (C) | 1,050-1,200 | 150,000,000-175,000,000 |

In some embodiments, a component or item (e.g. substrate 17b of FIG. 2) is deemed to be rigid when it is constructed of a material that has a Young's modulus of 20 GPa or greater, 30 GPa or greater, 40 GPa or greater, 50 GPa or greater, 60 GPa or greater or 70 GPa or greater. In various embodiments, a material is deemed to be rigid when the Young's modulus for the material is a constant over a range of strains. Such materials are sometimes referred to as “linear” and are said to obey Hooke's law. Thus, in some embodiments, the substrate is made out of a linear material that obeys Hooke's law. Examples of such linear materials include, but are not limited to, steel, carbon fiber, and glass. Examples of non-linear materials are rubber and soil (except at very low strains). In other embodiments, a material is deemed rigid when the combination of material and dimensions are such that the material does not substantially deform when subjected to the effects of a force of 9.8 meters/sec.².

While some embodiments of suitable substrates 17b have rigid cylindrical shapes, such as solid rods, all or a portion of the elongated substrate may have a cross-section bounded by any desirable shape. The bounding shape of the substrate 17b may be circular, ovoid or another shape characterized by one or more smooth curved or arcuate surfaces, or any splice of smooth curved surfaces; have a linear nature, including triangular, rectangular, pentangular, hexagonal or any other number of linear segmented surfaces; be an n-gon, where n is 3, 5 or more; include at least one arcuate edge; include any combination of linear surfaces, arcuate surfaces or curved surfaces.

In some embodiments, a first portion of the substrate 17b is characterized by a first cross-sectional shape and a second portion of the substrate 17b is characterized by a second cross-sectional shape, where the first and second cross-sectional shapes are the same or different. For some examples, at least ten, twenty, thirty, forty, fifty, sixty, seventy, eighty, ninety or one-hundred percent of the length of the substrate 17b may be characterized by the first cross-sectional shape. In some embodiments, the first cross-sectional shape of the substrate 17b is planar (e.g., has no arcuate side) and the second cross-sectional shape has at least one arcuate side.

In various embodiments, the module(s) 16 may have a multi-facial, or omnifacial configuration, or otherwise be designed to capture light from directions both facing and not facing the initial light source. An example omnifacial topology of a module 16 may include the depicted cylindric or cylindric-like construction (e.g. FIG. 5), where the surface of the module has one continuous surface. In a multifacial configuration, the shape of the cross section of the module 16 can be described by any combination of straight lines and curved features. In some cases, the omnifacial and multifacial configurations are operable to receive light from differing orientations, including anti-parallel directions. In other embodiments, the module 16 may be bifacial, having two flat PV cells conjoined in opposite directions, such that light entering from either the top or the bottom would be received and converted to electric energy.

Further, the module 16 and any outer protective structure 21 (e.g. FIG. 5) may have the same or substantially same geometric shape. Alternatively, the module 16 and any associated outer protective structure 21 may have differing geometries (i.e. a bifacial solar cell disposed within a tubular or cylindrical outer protective structure 21). Accordingly, the modules 16 and outer protective structures 21 may thus have any suitable cross-sectional shapes, such as square, rectangular, elliptical, polygonal, or have a varying cross-sectional shape, and any desired overall shape and configuration.

Referring still to the example of FIG. 5, the photovoltaic cell(s) 17a may have any suitable form and the same functionality as described above with respect to the example of FIG. 1. In some embodiments, the photovoltaic cell 17a includes multiple layers of material circumferentially coating the substrate 17b. For example, a photovoltaic layer 25 may be sandwiched between a back electrode 26 and a front electrode 27.

The photovoltaic layer 25 may be disposed on the back electrode 26 and operable to produce an electric potential and electric current. The photovoltaic layer 25 may include any material or combinations of materials that produce a photovoltaic effect. For example, the photovoltaic layer 25 may include layers of differing charged semiconductor materials, where one overlays the other. Semiconductor materials, when used, may be formed, for example, as a hetero-junction semiconductor or semiconductor junction formed from a common substance with opposing layers having oppositely-doped characteristics. Any other suitable photovoltaic material(s) may be used, such as photoelectrochemical cells, polymer solar cells, organic-based photovoltaic materials, nanocrystal solar cells, polymers with nano particles mixed together to make a single multispectrum layer.

An example back electrode is one or more layer of conducting material disposed on the substrate 17b. An example front electrode 27 is a transparent conducting layer, such as transparent conductive oxide (not shown), disposed on the photovoltaic layer 25. For another example, the front electrode 27 may be a “net” or other configuration of otherwise non-transparent conductive material placed over the photovoltaic material and not covering the entire photovoltaic layer 25.

If desired, the annular volume between the photovoltaic structure 17 and the outer protective structure 21 may include material to assist in protecting the photovoltaic structure 17, a non-reactive gas or other suitable substance(s).

In some embodiments, the module 16 has an integral formation of a plurality of photovoltaic solar cells 17a coupled together electrically over a monolithic substrate 17b in an elongated structure. For instance, each photovoltaic cell 17a in a module may occupy a portion of an underlying substrate 17b common to the entire photovoltaic module 16 and the cells 17a electrically coupled together in series or parallel. In other embodiments, the module 16 may have a single photovoltaic cell 17a disposed on a substrate 17b. In yet other examples, the module 16 may include a plurality of photovoltaic cells 17a each made on their own individual substrates 17b and linked together electrically. The individual cells 17a may be coupled either serially, in parallel or a combination thereof. For example a photovoltaic module 16 may have 1, 2, 3, 4, 5 or more, 20 or more, or 100 or more such photovoltaic cells 17a.

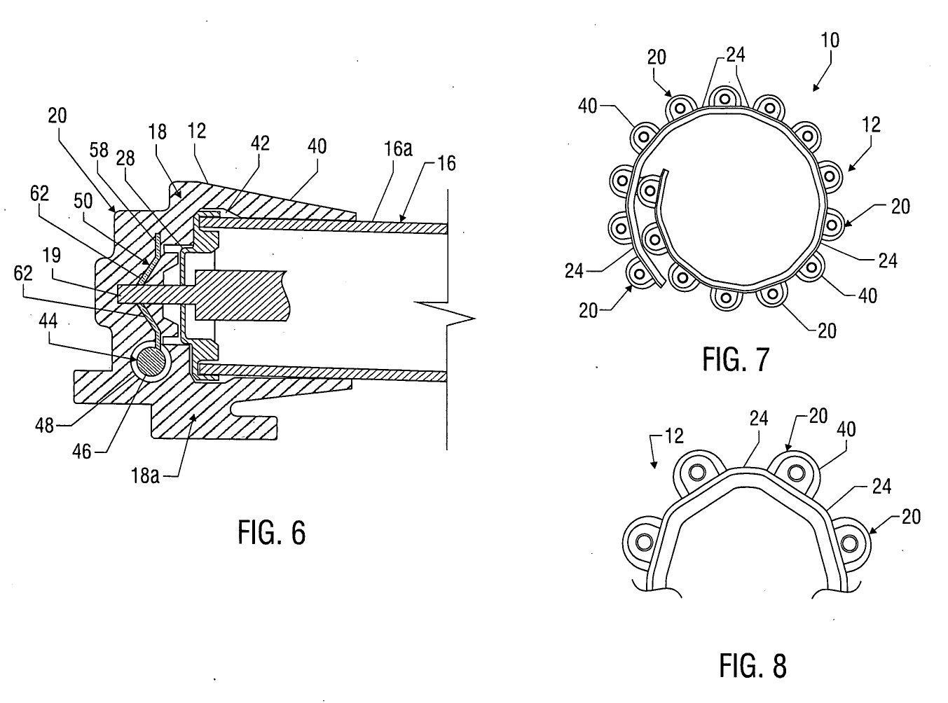

Referring back to the example of FIG. 4, each illustrated module 16 is sealed and includes an end cap 28 (e.g. FIG. 6) and at least one electrical output contact 19 at each end 18. The output contact 19 provides the electricity that is generated by the module 16. The illustrated end cap 28 may, if desired, provide a water-tight seal around the end of the module 16 and electrically isolate the output contact 19. In the particular arrangement of FIG. 4, the output contacts 19 at the first ends 18a (e.g. FIG. 6) of the modules 16 are anodes, while the output contacts 19 at the second ends 18b of modules 16 are cathodes, but any other arrangement may be employed. Each module 16 may include only a single output contact 19 or multiple output contacts 19 at any desired location (e.g. intermediate to its ends).

Additional description and details of the components, construction and operation of various examples of elongated photovoltaic modules and other components that may potentially be used with the carrier assembly 10 of the present disclosure may be found in U.S. patent application Ser. Nos. 11/378,835, 60/859,213, 60/859,212, 60/859,188, 60/859,033, 60/859,215, 60/861,162, 60/901,517, 61/001,605, 60/994,696 and all U.S. patent applications and patents claiming priority thereto, all of which have a common assignee as the present application and are hereby incorporated by reference herein in their entireties. Again, the present disclosure and appended claims are not limited by the structure, components, operation or other aspects of the photovoltaic modules (except as may be expressly recited in any particular claims and only with respect thereto).

The exemplary modules 16 of FIG. 4 are engaged in the carrier assembly 10 in a generally fixed or rigid relationship and are, thus, load bearing elements. In other configurations, one or more modules 16 may be movable. For example, the modules 16 may be engaged in the carrier assembly 10 so that they may be individually or collectively swiveled or tilted at angles relative to the assembly 10, such as to track the movement of the sun.

In accordance with the present disclosure, the carrier 12 may have any suitable form, construction and configuration. Further, if the carrier 12 is moveable between adjacent receptacles 20, it may be moveable in any desired manner. For example, the carrier 12 may be at least partially constructed of flexible material so that it is moveable, such as by flexing or bending, between adjacent receptacles 20. Some examples of such materials include rubber, shape memory composites and various plastics and plastic-based composites. In some instances, the carrier 12 may essentially string together the receptacles 20 so that it is loose or relaxed between adjacent receptacles 20, similar to a “rope ladder” or Christmas tree light structure.

If desired, the material composition of at least part of the carrier 12 may be selected for one or more other or additional purpose, such as to facilitate engagement with the modules 16, provide electrical insulation, assist in reducing stress applied to the modules 16, provide strength and durability, provide rigidity at portions of the carrier 12 that are not moveable, or any other desired purpose. In the embodiment of FIG. 4, the carrier 12 is constructed of a non-electrically conductive material, such as rubber, and formed by a molding or extrusion process. The illustrated carrier 12 includes a bridge portion 24 extending between each adjacent receptacle 20 and which is sufficiently flexible to bend as desired. In FIG. 7, the exemplary carrier 12 is shown bent at various bridge portions 24, and in FIG. 8, the (roughly estimated) deformation of the illustrated bridge portions 24 is shown. In other examples, the carrier 12 may be only partially constructed of a non-electrically conductive, bendable material, or only certain bridge portions 24 may be bendable or otherwise moveable. The illustrated carrier 12 may thus be movable between its original shape (e.g. FIG. 4) and one or more desired folded, coiled, or other overall different shape by bending at the appropriate bridge portions 24.

The amount of force, pressure or other action (if any) that may be required to cause the movement of the carrier 12 between receptacles 20 will likely depend upon the material composition and dimensions of the carrier(s) 12 and other design features of the carrier assembly 10, as well as the particular desired movability of the carrier 12. In some embodiments, the bridge portion 24 may be bendable when merely subjected to the force of gravity.

In various embodiments, a move mechanism (not shown) may be included between receptacles 20 on the carrier 12 to allow movement of the carrier 12 between receptacles 20. Move mechanisms are referred to herein as “hinged portions”, which includes any component(s) or device(s) associated with a carrier 12, or configuration of one or more component of a carrier 12 that allows movement of one receptacle 20 of the carrier 12 relative to an adjacent receptacle 20 of the carrier 12, other than by only the bending or flexing of the carrier 12. Move mechanisms may take any suitable form. In some embodiments, the move mechanisms may be integrally formed as part of the carrier 12 or connected with the carrier 12 in any desired manner. Some example move mechanisms that may be disposed on the carrier 12 between adjacent receptacles 20 are joints and hinges (not shown).

The ability to move or fold the carrier 12 between receptacles 20 may be useful for any desired purpose, such as ease of storage, transportation, delivery and/or handling of individual carriers 12 or a carrier assembly 10 with engaged modules 16. For example, in some embodiments, the carrier 12 may be “folded” into a container that is much smaller than the assembled carrier assembly 10 with modules 16, such as for storage and shipment. Thereafter the carrier 12 may be easily unfolded or removed from the container at its installation site, such as in a manner similar to a “rope ladder” or set of Christmas tree lights. However, it should be understood that the carrier 12 may, in some embodiments, not be moveable between receptacles 20.

Referring back to FIG. 4, any desired number of carriers 12 may be included in any desired configuration. In the embodiment shown, two identical opposing carriers 13, 14 are used. A first carrier 13 is shown engaged with a first end 18a of each illustrated module 16, while a second carrier 14 is shown engaged with the second (opposite) end 18b of each of the modules 16.

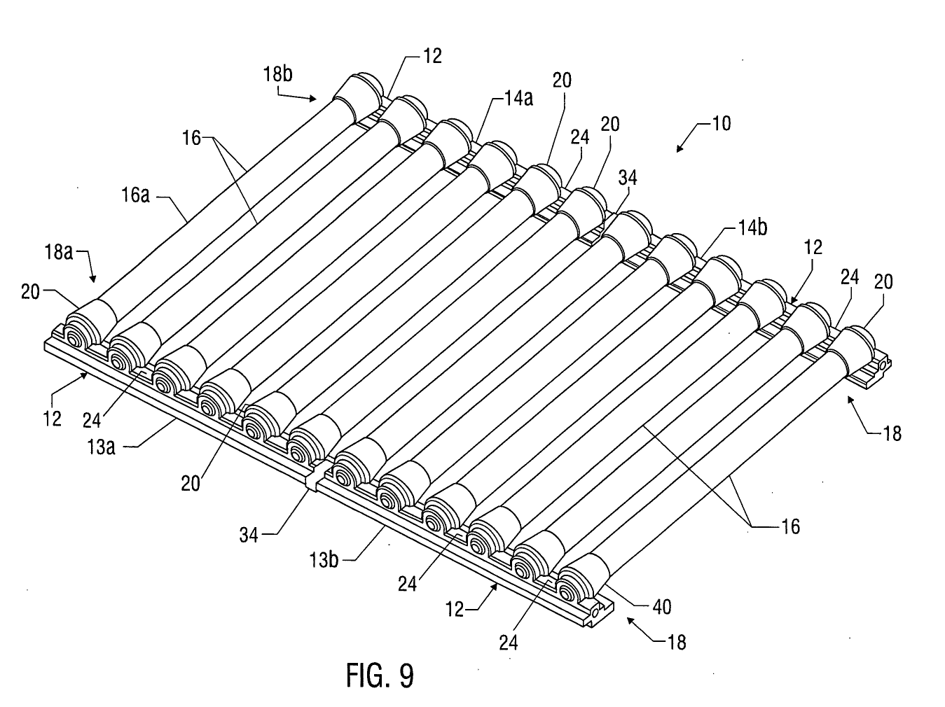

In other embodiments, two or more adjacent carriers 12 may be included, such as to increase photovoltaic energy collection of the carrier assembly 10, or for any other desired purpose. In FIG. 9, for example, the illustrated carriers 12 are interconnectable lengthwise (along their longitudinal axes), so that multiple carriers 12 may be aligned on either or both sides 18a, 18b of the modules 16. Each aligned set of carrier 13a, 13b and carriers 14a, 14b of this embodiment are interconnected with the use of a clip 34, respectively. However, any other suitable components or techniques may be used for interconnecting the carriers 12, such as by interlocking, matable or snapping engagement, friction fitting, screws or other connectors.

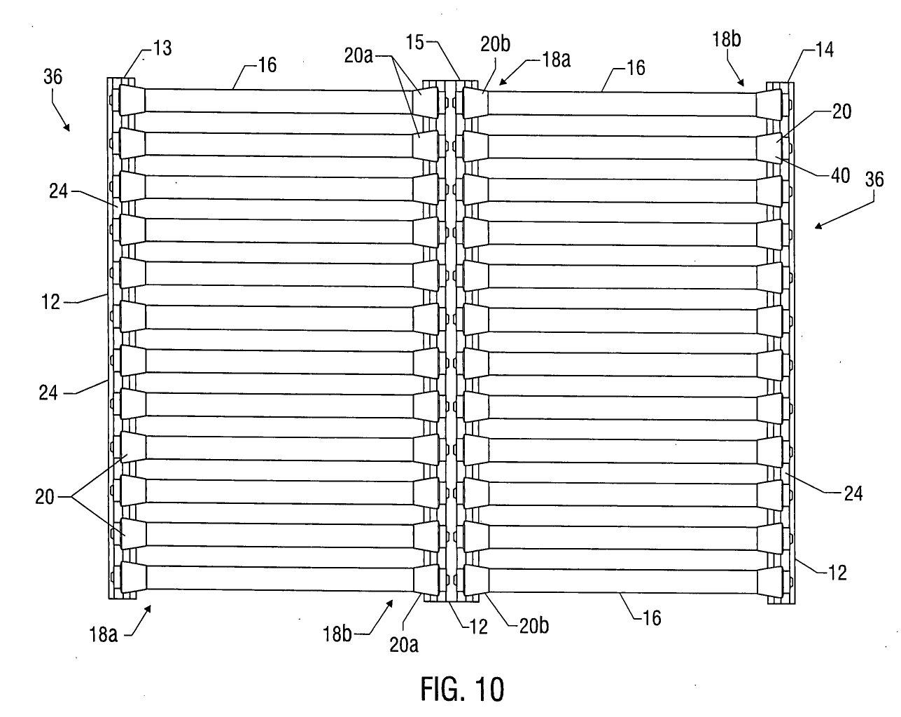

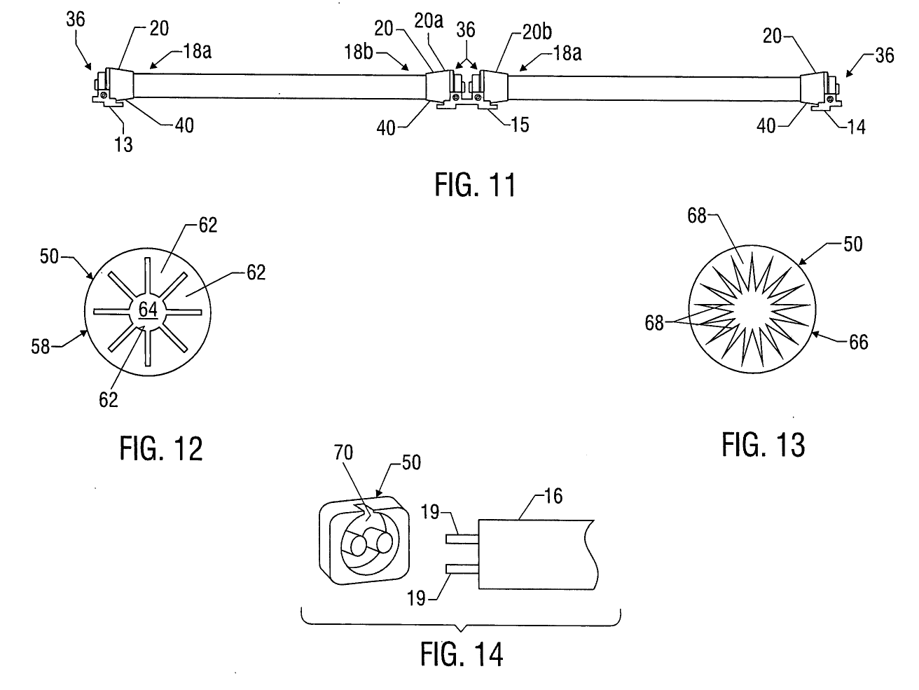

For another example, the carrier assembly 10 of FIG. 10 is capable of holding two rows of modules 16 side-by-side with the use of first, second and middle carriers 13, 14, 15. As shown in FIG. 11, the middle carrier 15 includes receptacles 20a, 20b facing in opposite directions. The middle carrier 15 is thus capable of holding the second end 18b of a first set of modules 16 on its left side and the first end 18a of a second set of modules 16 on its right side. In this embodiment, the first, second and middle carriers 13, 14 and 15 are moveable between adjacent receptacles 20 so that the entire carrier assembly 10 is movable between receptacles 20.

In other embodiments, a side-by-side arrangement may instead be configured with the use of a set of interconnecting back-to-back carriers 12 instead of a middle carrier 15. The back-to-back carriers (not shown) may be interconnectable at their outside surfaces 36 by interlocking, matable or snapping engagement, friction fitting, and/or with screws, clips or other connectors, or any other suitable method. For still another example arrangement of adjacent carriers, multiple carriers 12 may be interconnectable and layered above one another to create a multi-tiered carrier assembly (not shown).

Referring again to FIG. 4, the receptacles 20 may also have any suitable form, construction and configuration, as long as each receptacle 20 is capable of engaging at least one module 16. In some embodiments, the carrier 12 may be designed with receptacles 20 capable of engaging multiple modules 16. In the embodiment of FIG. 4, each receptacle 20 engages a single module 16. As shown in FIG. 6, the illustrated receptacle 20 includes a shell portion 40 that surrounds a cavity, or opening, 42 within which an end 18 of a module 16 is insertable and removable. In this example, the shell portion 40 is capable of grippingly engaging the outside surface 16a of the module 16 to assist in holding the module(s) 16 in the cavity 42. For example, the shell portion 40 may be shaped to assist in gripping the module 16, such as with a cone-like shape, and/or constructed of a gripping material, such as rubber. However, the shell portion 40 need not be designed or configured to assist in holding the module 16.

The receptacles 20 may be arranged in any desired configuration. In the embodiment of FIG. 4, for example, numerous receptacles 20 are aligned in a single row in spaced relationship along at least part of the length of each carrier 13, 14. However, as few as two receptacles 20 may be included in a carrier 12. For another example, multiple rows (not shown) of receptacles 20 may be provided on a carrier 12. If desired, the multiple rows of receptacles 20 may be located at differing heights on the carrier 20 with adjacent receptacles on adjacent rows staggered relative to one another, such as for optimal light absorption, or any other desired purpose.

Referring again to FIG. 6, the carrier 12 may also be capable of electrically connecting the module(s) 16 engaged in its receptacles 20. When included, any suitable components and techniques may be used for electrically connecting the carrier 12 to the engaged module(s) 16. In the embodiment shown, the carrier 12 includes at least one electrically conductive line (ECL) 44 that electrically connects the modules 16 disposed in its various receptacles 20. As used herein and in the appended claims, the term “electrically conductive line” and variations thereof means any material(s) or component(s) capable of electrically joining at least two elongated photovoltaic modules.

The electrically conductive line 44 may have any suitable construction and configuration. For example, the ECL 44 may be a metal ribbon or strip, or a series thereof. For another example, the ECL 44 may include a series of electrically conducting wires, strips or other members. In the embodiment of FIGS. 4 and 6, the ECL 44 is a bus-type connection line that includes a thin, flexible, metallic wire 46 coated with plastic, such as for flexibility and durability. The ECL 44 in the first carrier 13 connects all the (anode) output contacts 19 of the modules 16 to a common anode terminal (not shown), such as a commercially available male or female electrical plug or receptacle. Similarly, the ECL 44 in the second carrier 14 connects all the (cathode) output contacts 19 to a common cathode terminal (not shown). The illustrated modules 16 are thus connected in parallel. In this manner, the electrical connection between the modules 16 of this example is defined by two bus-like connections in the carrier assembly 10. For another example, the modules 16 may be arranged so that they are connected in series (not shown).

The ECL 44 may electrically connect the modules 16 in any desired manner. For example, the ECL 44 may be soldered directly (not shown) to the output contacts 19 of the modules 16. In the embodiment of FIG. 4, the ECL 44 extends through the length of the carrier 12 (including the bridge portions 24) and electrically connects to an output contact connector 50 (e.g. FIG. 6) disposed within the carrier 12 at each receptacle 20 and which engages the output contact 19 of the module 16 therein.

The ECL 44 and connectors 50 may be electrically connected together and disposed within the carrier 12 in any suitable manner. For example, the ECL 44 and connectors 50 may be formed integrally in a single unit, connected by solder, interlocking, matable or snapping engagement, friction fitting, or with the use of one or more connector, such as a clip. In the embodiment of FIG. 6, the ECL 44 and connectors 50 are connected by spot weld and embedded in the carrier 12. For example, the ECL 44 and connectors 50 may be placed into a mold form used for fabricating the carrier 12, wherein rubber or a rubber composite is thereafter injected or extruded. In some embodiments, the ECL 44 is disposed in a passageway 48 in the carrier 12. If desired, the passageway 48 may be wider than the ECL 44 to allow flexing of the ECL 44 and assist in protecting the ECL 44 from breakage or disconnection.

When included, the connector 50 may have any suitable form and construction and may electrically connect with the module(s) 16 in any desired manner. In the example of in FIG. 6, the illustrated connector 50 is an electrically conductive, deformable leaf member 58 embedded in the carrier 12. The leaf member 58 includes numerous leaves 62 (e.g. FIG. 12) that crimp or deform into engagement with an output contact 19 of the module 16 when the output contact 19 of the module 16 is pressingly engaged with or pushed into an opening 64 of the leaf member 58.

For another example, in FIG. 13, the connector 50 is an electrically conductive, deformable gripper 66 with saw teeth 68 that crimp or deform onto the output contact 19 of a module 16. For yet another example, in FIG. 14, the connector 50 includes a passage 70 (akin to a typical overhead fluorescent light fixture receptacle) within which one or more output contact 19 of a module 16 is twisted into locking engagement. In even further examples, the connector (not shown) may be designed for screwing, press fit, snapping or mating engagement with one or more output contact 19.

If desired, in addition to providing an electrical connection with one or more module 16, the connector 50 may assist in mechanically engaging, or holding, the module 16 in the receptacle 20. For example, each of the connectors 50 of FIGS. 12-14 is capable of releasably gripping an output contact 10 of a module 16, thus assisting in holding the module 16 in the receptacle 20 of a carrier 12.

Other examples and details of ECL's and connectors which may, in certain instances, be used with the carrier assembly 10 of the present disclosure and details of their construction and operation may be described in U.S. patent application Ser. Nos. 11/378,835, 60/859,213, 60/859,212, 60/859,188, 60/859,033, 60/859,215, 60/861,162, 60/901,517, 61/001,605, 60/994,696, and all U.S. patent applications and patents claiming priority thereto, all of which have a common assignee as the present application and are hereby incorporated by reference herein in their entireties.

In another independent aspect of the present disclosure, the electrical connection to multiple modules 16 in the carrier 12 may be sealed or isolated, such as to prevent the electrical connection from contact with undesirable fluids, gasses, particles or other materials or substances, or for any other desired purpose. As used throughout this patent, the terms “seal”, “sealingly engaged” and variations thereof generally refer to an arrangement, condition or state in which the entry of an undesirable quantity of undesirable fluids, gasses, particles or other materials or substances is prevented or preventable. In some instances, for example, a water-tight or water-resistant seal may be desired. For another example, the seal may be sufficient so the module and carrier engaged therewith satisfies the salt-water dunk safety test presently utilized for testing solar panels.

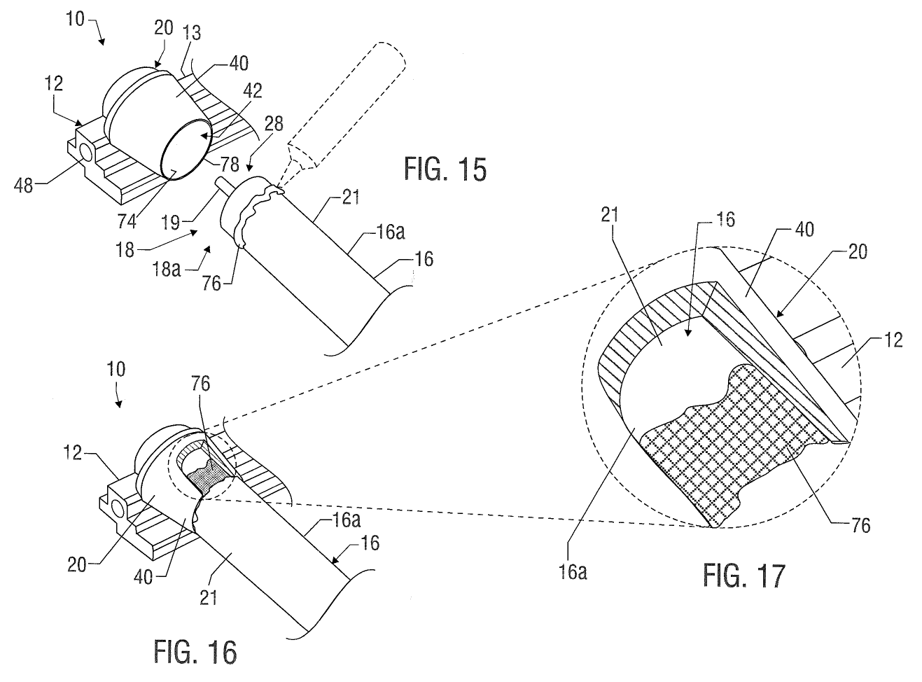

Any suitable components and techniques may be used to seal the electrical connection to the modules 16. In the embodiment of FIG. 15, for example, a sealant 76 is disposed between the module 16 and the inner surface 74 of the shell portion 40 of the receptacle 20 around the circumference of the cavity 42 and/or module 16. The sealant 76 may be any suitable material, substance or combination thereof, such as, for example, a commercially available silicon-based sealant or a time-released substance formed into one of the components. Further, the sealant 76 may have any desired suitable properties, such as bonding or non-bonding capabilities. Thus, the present disclosure, appended claims and the specification and claims of any patent application or patent claiming priority hereto are not limited by the sealant, its properties, composition, form, application or other details.

In the embodiment of FIG. 15, the sealant 76 is shown placed upon the outer protective structure 21, or outside surface 16a, of the module 16 proximate to the end cap 28 or end 18a of the module 16 at a location that will correspond to approximately the mid-point of the shell portion 40 of the receptacle 20 when the module 16 is engaged in the receptacle 20. However, the sealant 76 may be located at any desired position or positions on the module 16, as long as it ultimately forms a seal with the receptacle 20. Moreover, the sealant 76 may instead be placed upon the inner surface 74 of the shell portion 40 or upon one or more other portions of the receptacle 20, or on both the module 16 and receptacle 20.

Any desired technique may be used for providing the sealant 76. For example, the sealant may manually beaded or drizzled down-down onto the desired component, applied in an automated process, included in the manufacturing or assembly of the components, such as with a time-release capability, or otherwise.

Now referring to FIGS. 16 and 17, as the module 16 and receptacle 20 of this embodiment are engaged, such as by pressing or snapping the module 16 into the cavity 42 through the cavity opening 78, and an electrical connection is made with the output contact 19 (FIG. 15) of the illustrated module 16, the exemplary sealant 76 forms a seal between the module and the receptacle 20 around the perimeter of the module 16. The module 16 and receptacle 20 become sealingly engaged. In this example, since the remainder of the receptacle 20 (and carrier 12) is otherwise sealed relative to the electrical connection with the output contact 19, the cavity 42, first end 18a of the module 16 and output contact 19 are thus sealed-off from the external environment, providing a water-tight enclosure around the electrical connection.

If desired, the sealing engagement of the module 16 and receptacle 20 may be used in the context of any desirable carrier assembly, such as the assemblies 10 of FIGS. 4, 9 and/or 10. In such examples, if the overall assembly 10 is sealed relative to the ECL 44, output contact connectors 50 and/or other electrical components therein, the sealing engagement of each receptacle 20 and corresponding module 16 will allow the entire carrier assembly 10 to be sealed around the electrical connections/system therein.

Accordingly, in some embodiments, the present disclosure involves an apparatus for sealing an electrical connection to at least one elongated photovoltaic module. The elongated photovoltaic module includes at least one electrical output contact extending therefrom and the apparatus includes at least one carrier. The carrier includes at least one receptacle and at least one electrically conductive line. The receptacle includes at least one cavity and is sealingly engageable with the elongated photovoltaic module around its output contact. The electrically conductive line is at least partially accessible through the cavity and is electrically connectable with the output contact of the elongated photovoltaic module. The cavity of the receptacle is thus sealable around the electrical connection formed between the electrically conductive line and the output contact of the elongated photovoltaic module.

In various embodiments, the present disclosure involves an apparatus for sealing an electrical connection to at least one elongated photovoltaic module. The apparatus includes at least one carrier, and the elongated photovoltaic module includes at least one electrical output contact extending from a first end thereof and an outer protective structure. The carrier includes at least one receptacle and at least one output contact connector. The receptacle includes at least one cavity and is sealingly engageable with the outer protective structure of the elongated photovoltaic module around the first end and output contact thereof. The output contact connector is at least partially accessible through the cavity and is electrically connectable with the output contact of the elongated photovoltaic module. The cavity of the receptacle is sealable around the electrical connection formed between the output contact connector and the output contact of the elongated photovoltaic module.

The present disclosure also includes embodiments of a carrier assembly capable of retaining a plurality of elongated photovoltaic modules. Each elongated photovoltaic module includes first and second ends. The apparatus includes at least first and second carriers. The first carrier includes a plurality of receptacles, each being sealingly engageable with at least one elongated photovoltaic module proximate to the first end thereof. The first carrier also includes at least one electrically conductive line capable of electrically connecting, through one of the receptacles of the first carrier, to each elongated photovoltaic module engaged with the first carrier. The second carrier includes a plurality of receptacles, each being sealingly engageable with at least one elongated photovoltaic module proximate to the second end thereof. The second carrier also includes at least one electrically conductive line capable of electrically connecting, through one of the receptacles of the second carrier, to each elongated photovoltaic module engaged with the second carrier. Thus, the electrical connections formed between the first and second carriers and the elongated photovoltaic modules engaged therewith may be isolated from contact with undesirable fluids, gasses, particles, and other undesirable materials and substances.

There are also embodiments of the present disclosure involving apparatus for producing electric energy. The apparatus includes at least two elongated photovoltaic modules and first and second module carriers. Each elongated photovoltaic module includes first and second ends, an active photovoltaic structure and a protective structure surrounding the photovoltaic structure. The photovoltaic structure includes a rigid substrate, a back electrode disposed on the rigid substrate, a photovoltaic layer disposed on the back electrode and a front electrode disposed on the photovoltaic layer. The photovoltaic layer is operable to produce an electric potential and electric current. The first and second module carriers are coupled to the first and second respective ends of each of the elongated photovoltaic modules.

Each of the first and the second module carriers includes first and second receptacles. Each receptacle is operable to engage a first elongated photovoltaic module proximate to an end thereof and includes an electrical connection thereto. Each set of receptacles is sealingly engageable with the first and second elongated photovoltaic modules around the electrical connections formed therewith, respectively.

Some embodiments of the present disclosure involve a method of providing a sealed electrical connection between an elongated photovoltaic module and a carrier. The elongated photovoltaic module including at least one electrical output contact extending therefrom, and the carrier includes an electrically conductive line. The method includes forming, as part of the carrier, a receptacle having a cavity and an opening to the cavity. Access to the electrically conductive line is provided through the cavity. At least one sealant is provided on at least one among the outer surface of the elongated photovoltaic module and the inner surface the receptacle. The elongated photovoltaic module is inserted through the opening into the cavity so that the electrical output contact of the elongated photovoltaic module electrically engages the electrically conductive line. The sealant is allowed to form a seal between the receptacle and the elongated photovoltaic module around the electrical connection formed between the electrical output contact of the elongated photovoltaic module and the electrically conductive line.

Many embodiments of the present disclosure involve an apparatus for producing electric energy from light energy that includes an elongated photovoltaic module and a cover sealingly engaged to the elongated photovoltaic module. The elongated photovoltaic module includes first and second ends, an active photovoltaic structure, a protective structure surrounding the active photovoltaic structure and at least one electrical output contact. The active photovoltaic structure includes a rigid substrate, a back electrode disposed on the rigid substrate, a photovoltaic layer disposed on the back electrode and a front electrode disposed on the photovoltaic layer.

The cover is sealingly engaged to the elongated photovoltaic module around at least one electrical output contact thereof. The cover includes at least one electrical connector operable to electrically engage at least one electrical output contact of the elongated photovoltaic module. A water-tight seal is created between the cover and the elongated photovoltaic module around at least one electrical output contact thereof.

Accordingly, the present disclosure includes features and advantages which are believed to enable it to advance photovoltaic energy absorption or collection technology including characteristics and advantages described above and in the appended claims and/or shown in the accompanying drawings, and additional features and benefits apparent to those skilled in the art upon consideration of this patent. However, each of the appended claims does not require each of the components and acts described above or shown in the drawings and is in no way limited to the above-described examples and methods of assembly and operation. Any one or more of such components, features and processes may be employed in any suitable configuration without inclusion of other such components, features and processes. Moreover, the present disclosure includes additional features, capabilities, functions, methods, uses and applications that have not been specifically addressed herein but are, or will become, apparent from the description herein, the appended drawings and claims.

The methods described above and which may be claimed herein and any other methods which may fall within the scope of the appended claims can be performed in any desired suitable order and are not necessarily limited to the sequence described herein or as may be listed in any appended claims. Further, the methods of the present disclosure do not necessarily require use of the particular examples shown and described in the present specification, but are equally applicable with any other suitable structure, form and configuration of components.

While examples have been shown and described, many variations, modifications and/or changes of the system, apparatus and methods herein, such as in the components, details of construction and operation, arrangement of parts and/or methods of use, are possible, contemplated by the patent applicant(s), within the scope of the appended claims, and may be made and used by one of ordinary skill in the art without departing from the spirit or teachings of this disclosure and scope of the appended claims. Thus, all matter herein set forth or shown in the accompanying drawings should be interpreted as illustrative, and the scope of this disclosure and the appended claims should not be limited to the examples described and shown herein.

1. An apparatus for sealing an electrical connection to at least one elongated photovoltaic module, the at least one elongated photovoltaic module including at least one electrical output contact extending therefrom, the apparatus comprising:
at least one carrier including,
at least one receptacle, at least one said receptacle having at least one cavity and being sealingly engageable with the at least one elongated photovoltaic module around the at least one electrical output contact of the at least one elongated photovoltaic module, and
at least one electrically conductive line at least partially accessible through at least one said cavity, at least one said electrically conductive line being electrically connectable with at least one electrical output contact of the at least one elongated photovoltaic module,
wherein at least one said cavity is sealable around the electrical connection formed between said at least one electrically conductive line and the at least one electrical output contact of the elongated photovoltaic module.

2. The apparatus of claim 1 wherein said at least one carrier further includes at least one output contact connector at least partially accessible through at least one said cavity, at least one said output contact connecter being electrically connectable with at least one said electrically conductive line and at least one electrical output contact of at least one elongated photovoltaic module

3. The apparatus of claim 2 wherein said at least one output contact connector is at least one among a saw-tooth member and a leaf member.

4. The apparatus of claim 1 wherein said at least one receptacle is constructed of non-electrically conductive material.

5. The apparatus of claim 4 wherein said at least one receptacle includes at least one shell portion that forms at least one said cavity and is capable of grippingly engaging at least one elongated photovoltaic module.

6. The apparatus of claim 5 wherein said at least one shell portion includes an opening into at least one said cavity through which at least one elongated photovoltaic module is insertable and is otherwise sealed around said at least one cavity.

7. The apparatus of claim 1 wherein each elongated photovoltaic module includes first and second ends and at least one electrical output contact extending therefrom, further including first and second said carriers, each of said first and second carriers including a plurality of said receptacles, wherein each of said plurality of receptacles of said first carrier is sealingly engageable with a photovoltaic module proximate to its respective first end and each of said plurality of receptacles of said second carrier is sealingly engageable with a photovoltaic module proximate to its respective second end.

8. The apparatus of claim 1 further including at least one sealant provided upon each elongated photovoltaic module.

9. The apparatus of claim 1 further including at least one sealant provided upon the inner surface of each said receptacle that surrounds said at least one corresponding cavity.

10. The apparatus of claim 1 further including at least one sealant provided upon each elongated photovoltaic module and the inner surface of each said receptacle that surrounds at least one said corresponding cavity.

11. An apparatus for sealing an electrical connection to at least one elongated photovoltaic module, the at least one elongated photovoltaic module including at least one electrical output contact extending from a first end of the elongated photovoltaic module and an outer protective structure, the apparatus comprising:
at least one carrier including,
at least one receptacle, at least one said receptacle having at least one cavity and being sealingly engageable with the outer protective structure of the at least one elongated photovoltaic module around the first end and the at least one electrical output contact of the at least one elongated photovoltaic module, and
at least one output contact connector at least partially accessible through at least one said cavity, at least one said output contact connector being electrically connectable with at least one electrical output contact of the at least one elongated photovoltaic module,
wherein at least one said cavity is sealable around the electrical connection formed between said at least one output contact connector and the at least one electrical output contact of the at least one elongated photovoltaic module.

12. The apparatus of claim 11 wherein at least one said receptacle is constructed of non-electrically conductive material.

13. The apparatus of claim 12 wherein said at least one receptacle includes at least one shell portion that forms at least one said cavity and is capable of grippingly engaging at least one elongated photovoltaic module.

14. The apparatus of claim 11 further including at least one sealant provided upon the outer protective structure of each elongated photovoltaic module.

15. The apparatus of claim 11 further including at least one sealant provided upon the inner surface of each said receptacle that surrounds said at least one corresponding cavity.

16. The apparatus of claim 11 further including at least one sealant provided upon the outer protective structure of each elongated photovoltaic module and the inner surface of each said receptacle that surrounds said at least one corresponding cavity.

17. A carrier assembly capable of retaining a plurality of elongated photovoltaic modules, each elongated photovoltaic module including first and second ends, the apparatus comprising:
at least first and second carriers,
said first carrier including a plurality of receptacles, each said receptacle being sealingly engageable with at least one elongated photovoltaic module proximate to the first end thereof, said first carrier further including at least one electrically conductive line capable of electrically connecting, through one of said receptacles of said first carrier, to each elongated photovoltaic module engaged with said first carrier, and
said second carrier including a plurality of receptacles, each said receptacle being sealingly engageable with at least one elongated photovoltaic module proximate to the second end thereof, said second carrier further including at least one electrically conductive line capable of electrically connecting, through one of said receptacles of said second carrier, to each elongated photovoltaic module engaged with said second carrier,
wherein the electrical connections formed between said first and second carriers and the elongated photovoltaic modules engaged therewith may be isolated from contact with undesirable fluids, gasses, particles and other materials and substances.

18. The carrier assembly of claim 17 wherein each elongated photovoltaic module includes at least one electrical output contact at each of its first and second ends, wherein each said carrier includes a plurality of output contact connectors, each said output contact connector being electrically connectable between at least one electrical output contact of at least one elongated photovoltaic module and at least one said electrically conductive line.

19. The carrier assembly of claim 17 wherein each elongated photovoltaic module includes at least one electrical output contact extending through an end cap at each end thereof, each said end cap providing a water-tight seal around the respective end of the respective elongated photovoltaic module and electrically isolating the corresponding electrical output contact, wherein at least one said electrically conductive line of each said carrier is capable of electrically connecting to at least one electrical output contact of at least one elongated photovoltaic module.

20. The carrier assembly of claim 11 wherein said at least first and second carriers engaged with the plurality of photovoltaic modules satisfies the salt-water dunk safety test.

21. An apparatus for producing electric energy, the apparatus comprising:
at least two elongated photovoltaic modules, each said elongated photovoltaic module having a first end and a second end, each said elongated photovoltaic module comprising
an active photovoltaic structure comprising
a rigid substrate,
a back electrode disposed on said rigid substrate,
a photovoltaic layer disposed on said back electrode, said photovoltaic layer operable to produce an electric potential and electric current, and
a front electrode disposed on said photovoltaic layer, and
a protective structure surrounding said active photovoltaic structure;
a first module carrier coupled to said first end of each of said at least two elongated photovoltaic modules; and
a second module carrier coupled to said second end of each of said at least two elongated photovoltaic modules,
said first and the second module carriers each comprising
a first receptacle operable to engage a first said elongated photovoltaic module proximate to an end thereof and including an electrical connection to said first elongated photovoltaic module, and
a second receptacle operable to engage a second said elongated photovoltaic module proximate to an end thereof and including an electrical connection to said second elongated photovoltaic module,
said first and second receptacles being sealingly engageable with said first and second elongated photovoltaic modules around the electrical connections formed therewith respectively,
whereby a water-tight seal is formed around the electrical connections between said first and second module carriers and the elongated photovoltaic modules engaged therewith.

22. The apparatus of claim 21 wherein each said elongated photovoltaic module further includes an electrical output contact extending through an end cap at each end thereof, each said end cap providing a water-tight seal around the end of said respective elongated photovoltaic module and electrically isolating said corresponding electrical output contact, wherein each said receptacle of said first and second module carriers includes an electrical connection to at least one of said electrical output contacts of said elongated photovoltaic modules.

23. A method of providing a sealed electrical connection between an elongated photovoltaic module and a carrier, the elongated photovoltaic module including at least one electrical output contact extending therefrom and the carrier including an electrically conductive line, the method comprising:
as part of the carrier, forming a receptacle having a cavity and an opening to the cavity;
providing access to the electrically conductive line through the cavity;
providing at least one sealant on at least one among the outer surface of the elongated photovoltaic module and the inner surface the receptacle that surrounds the cavity;
inserting the elongated photovoltaic module through the opening into the cavity so that the electrical output contact of the elongated photovoltaic module electrically engages the electrically conductive line, and
allowing the sealant to form a seal between the receptacle and the elongated photovoltaic module around the electrical connection formed between the electrical output contact of the elongated photovoltaic module and the electrically conductive line.

24. An apparatus for producing electric energy from light energy, the apparatus comprising:
an elongated photovoltaic module, said elongated photovoltaic module having first and second ends, said elongated photovoltaic module including
an active photovoltaic structure comprising,
a rigid substrate,
a back electrode disposed on said rigid substrate,
a photovoltaic layer disposed on said back electrode, said photovoltaic layer operable to produce an electric potential and electric current, and
a front electrode disposed on said photovoltaic layer,
a protective structure surrounding said active photovoltaic structure and
at least one electrical output contact coupled to said active photovoltaic structure, said at least one electrical output contact being operable to carry an electric charge away from said active photovoltaic structure, said at least one electrical output contact being disposed on said first end of said elongated photovoltaic module; and
a cover sealingly engaged to said elongated photovoltaic module proximate to said first end thereof and around at least one said electrical output contact of said elongated photovoltaic module,
said cover including at least one electrical connector operable to electrically engage at least one said electrical output contact of said elongated photovoltaic module,
wherein a water-tight seal is created between said elongated photovoltaic module and said cover and around at least one said electrical output contact of said elongated photovoltaic module.
